(19) United States
(12) Patent Application Publication
(10) Pub. No.: US 2019/0221721 A1
(43) Pub. Date: Jul. 18, 2019

(54) QUANTUM STRUCTURE LIGHT-EMITTING MODULE

(71) Applicants: EFUN TECHNOLOGY CO., LTD., Tainan City (TW); SIC TECHNOLOGY CO. LTD, Hsinchu City (TW); SIC TECHNOLOGY CO., LIMITED, Hong Kong (HK)

(72) Inventors: Shih-Chieh TANG, Tainan City (TW); Ying-Tsung LU, Tainan City (TW); Shien-Tsung WU, Hsinchu City (TW); Wan-Shan LEE, Tainan City (TW)

(21) Appl. No.: 16/332,322

(22) PCT Filed: Aug. 14, 2017
(86) PCT No.: PCT/IB2017/054934

§ 371 Date: Mar. 11, 2019

(30) Foreign Application Priority Data
Sep. 13, 2016 (TW) 105129771
Nov. 15, 2016 (TW) 105137238

(51) Int. Cl. H01L 33/50; G02B 6/02; G02F 1/1335; H01L 25/075

(52) U.S. Cl. CPC H01L 33/502; G02B 6/0229; G02F 1/133603; G02F 1/133615; G02F 2001/133614; H01L 33/507; H01L 33/505; G02F 2001/133607; H01L 25/0753

(57) ABSTRACT

A quantum structure light-emitting module includes a quantum structure thin film and a light-emitting unit. The quantum structure thin film includes first and second substrates, and an excitation layer that is disposed between the first and second substrates, and that includes multiple quantum structures, which are quantum dots or quantum rods and which are made of cesium lead halide or organic ammonium lead halide. The light-emitting unit includes a first light-emitting element emitting a blue light that enters the excitation layer to excite the quantum structures to emit a green light, and a second light-emitting element emitting a red light. The blue, red and green lights are mixed and exit the second substrate.

### FIELD

The disclosure relates to a quantum structure light-emitting module, more particularly to a quantum structure light-emitting module including multiple quantum structures that are made of one of cesium lead halide and organic ammonium lead halide.

### BACKGROUND

A conventional quantum structure light-emitting module includes a light-emitting unit and a quantum structure thin film including a plurality of quantum dots. The light-emitting unit emits a first light to excite the quantum structure thin film to emit a second light, which mixes with the first light to form a desired output light. For example, a blue light-emitting unit emits a blue light to excite the quantum dots to emit a red light and a green light, which mix with the blue light to form a white light. The light response property of the quantum dots can be adjusted by changing the size or material of the quantum dots.

The quantum structure light-emitting module can be used in a backlight module of a display device. The display device including the quantum structure light-emitting module has superior color level, chromaticity, color gamut, and color saturation.

Conventionally, cadmium-containing semiconductor materials, such as cadmium sulfide, cadmium selenide, cadmium telluride, etc., are widely used for making the quantum dots. However, the toxic nature of the cadmium-containing semiconductor materials has driven scientists to seek for alternative materials, such as CsPbX₃, in which X can be fluorine, bromine, iodine, or combinations thereof. The light emitted by the quantum dots may be altered by changing the ratio of fluorine, bromine, and iodine, or by changing the size of the quantum dots. A blue-light-emitting unit is often used for exciting the CsPbX₃ quantum dots to obtain red and green lights. However, such excitation mechanism has a problem of having insufficient amount of red light, resulting in inferior color gamut of the display device.

### SUMMARY

Therefore, an object of the present disclosure is to provide a quantum structure light-emitting module that can alleviate at least one of the drawbacks associated with the prior art.

According to an aspect of this disclosure, a quantum structure light-emitting module includes a quantum structure thin film and a light-emitting unit.

The quantum structure thin film includes a first substrate, a second substrate and an excitation layer. The first substrate has a first surface and an incident surface opposite to the first surface. The second substrate is spaced apart from the first substrate, and has a second surface facing the first surface of the first substrate and a light exiting surface opposite to the second surface. The excitation layer is disposed between the first surface of the first substrate and the second surface of the second substrate, and includes a plurality of quantum structures. The quantum structures are one of quantum dots and quantum rods, and are made of one of cesium lead halide and organic ammonium lead halide.

The light-emitting unit is spaced apart from the quantum structure thin film, and includes a first light-emitting element emitting a blue light and a second light-emitting element emitting a red light.

The blue light emitted by the first light-emitting element and the red light emitted by the second light-emitting element pass through the first substrate and enter the excitation layer. The blue light excites the quantum structures to emit a green light. The red light, the blue light and the green light are mixed and exit the light exiting surface of the second substrate.

### BRIEF DESCRIPTION OF THE DRAWINGS

Other features and advantages of the disclosure will become apparent in the following detailed description of the embodiments with reference to the accompanying drawings, of which:

FIG. 1 is a fragmentary cross-sectional side view of a first embodiment of a quantum structure light-emitting module according to the present disclosure;

FIG. 2 is a fragmentary cross-sectional side view of a second embodiment of the quantum structure light-emitting module according to the present disclosure;

FIG. 3 is a fragmentary cross-sectional side view of a third embodiment of the quantum structure light-emitting module according to the present disclosure;

FIG. 4 is a fragmentary schematic view of the third embodiment, showing relative position of a light-emitting unit and a light guide plate of the third embodiment; and

FIG. 5 is a fragmentary cross-sectional side view of a fourth embodiment of the quantum structure light-emitting module according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

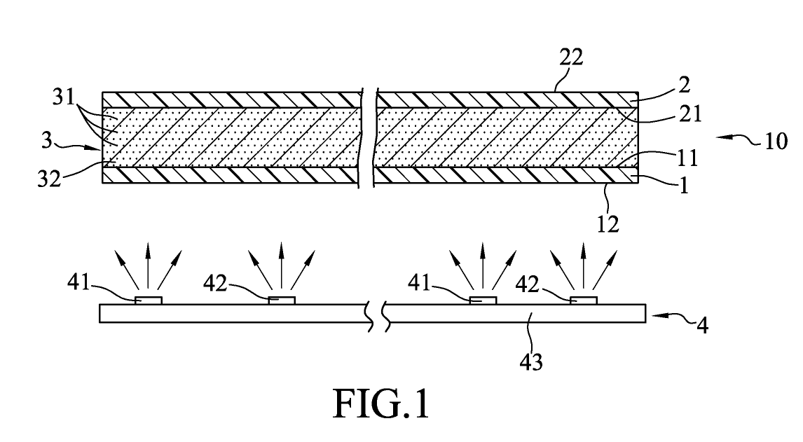

Referring to FIG. 1, a first embodiment of a quantum structure light-emitting module according to the present disclosure includes a quantum structure thin film 10 and a light-emitting unit 4. The quantum structure light-emitting module of this disclosure may be used in a display device (not shown).

The quantum structure thin film 10 includes a first substrate 1, a second substrate 2 and an excitation layer 3. The first substrate 1 has a first surface 11 and an incident surface 12 opposite to the first surface 11. The second substrate 2 is spaced apart from the first substrate 1, and has a second surface 21 facing the first surface 11 of the first substrate 1 and a light exiting surface 22 opposite to the second surface 21. The first substrate 1 and the second substrate 2 are each made of polyethylene terephthalate, cyclic olefin copolymer, polyimide, polyethersulfone, polyethylene naphthalate, polycarbonate, and combinations thereof.

The excitation layer 3 is disposed between the first surface 11 of the first substrate 1 and the second surface 21 of the second substrate 2, and includes a main body 32 and a plurality of quantum structures 31 distributed in the main body 32. The quantum structures 31 are excitable by a blue light to emit a green light. The quantum structures 31 are one of quantum dots and quantum rods. When the quantum structures 31 are quantum dots, the quantum structures 31 may each have a dimension ranging from 9 nm to 13 nm, such that the green light emitted by the quantum structures 31 is close to pure green, allowing the display device to have superior color gamut. The quantum structures 31 are made of one of cesium lead halide and organic ammonium lead halide. In this embodiment, the cesium lead halide is CsPbBr₃, and the organic ammonium lead halide is CH₃NH₃PbBr₃. By using the abovementioned perovskite material, the quantum structures 31 are free of cadmium to be environmentally friendly.

In certain embodiments, a surface of each of the first substrate 1 and the second substrate 2 may be formed with a water-resistant film, which can prevent the moisture from penetrating through the first substrate 1 and the second substrate 2 and affecting the excitation layer 3.

When making the excitation layer 3, the quantum structures 31 are immersed into an oleic acid solution or an oleylamine solution that has a predetermined concentration for a predetermined period to obtain the quantum structures 31 with desired dimensions. The oleic acid solution or the oleylamine solution also improves the light stability of the quantum structures 31. Afterwards, the treated quantum structures 31 are distributed in a colloidal system, which may be made of a light-transmissible resin, and may serve as a light homogenizer. Then the colloidal system with the quantum structures 31 may be coated on the first surface 11 of the first substrate 1 or the second surface 21 of the second substrate 2 to form the main body 32 distributed with the quantum structures 31. Based on actual requirements, the excitation layer 3 may be subjected to annealing to change the bandgap and decrease defects of the quantum structures 31 to improve light efficiency of the excitation layer 3.

The light-emitting unit 4 is spaced apart from the quantum structure thin film 10, and includes a circuit board 43. The light-emitting unit 4 further includes a plurality of first light-emitting elements 41 and a plurality of second light-emitting elements 42 that are alternatingly arranged on the circuit board 43. Each of the first light-emitting elements 41 may be a blue light-emitting diode that is capable of emitting a blue light. Each of the second light-emitting elements 42 may be a red light-emitting diode that is capable of emitting a red light. In certain embodiments, each of the second light-emitting elements 42 may include potassium fluorosilicate phosphor. Specifically, each of the second light-emitting elements 42 may include K₂SiF₆:Mn⁴⁺ phosphor, which allows the second light-emitting element 42 to emit the red light with narrow full width at half maximum, high energy, such that the color gamut of the display device is improved.

The blue light emitted by the light-emitting elements 41 and the red light emitted by the second light-emitting elements 42 pass through the first substrate 1 and enter the excitation layer 3. The blue light excites the quantum structures 31 to emit the green light. The red light, the blue light and the green light are mixed to forma white light and exit the light exiting surface 22 of the second substrate 2. The green light may have a dominant wavelength ranging from 520 nm to 540 nm.

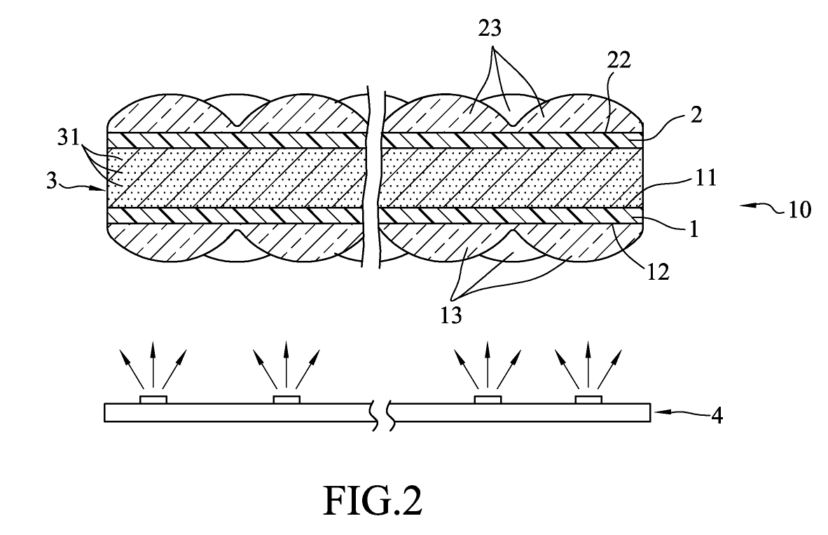

Referring to FIG. 2, a second embodiment of the quantum structure light-emitting module according to the present disclosure has a structure modified from that of the first embodiment. In the second embodiment, the first substrate 1 further has a plurality of first microstructures 13 that are formed on the incident surface 12, and the second substrate 2 further has a plurality of second microstructures 23 that are formed on the light exiting surface 22. The first microstructures 13 and the second microstructures 23 may improve light diffusion and light homogenization of the second embodiment, and may be made of Poly (methyl methacrylate), polyurethane, silicone, and combinations thereof. The shape of each of the first microstructures 13 and the second microstructures 23 may be identical or different from each other, and may be conical, semicircular, hexagonal, or irregular. The first microstructures 13 refract incident lights, thereby increasing the number of optical paths of the blue light in the excitation layer 3 to more effectively excite the quantum structures 31, thereby allowing the display device to achieve improved color gamut and color saturation. The second microstructures 23 alleviate total reflection of exiting light, thereby improving light extraction efficiency of the second embodiment.

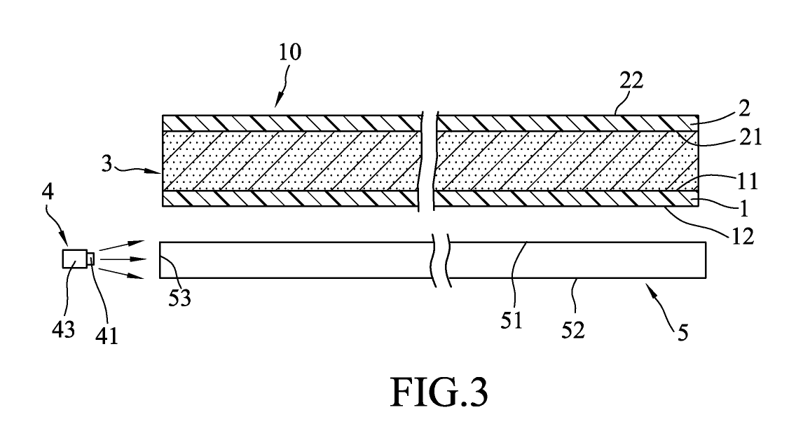

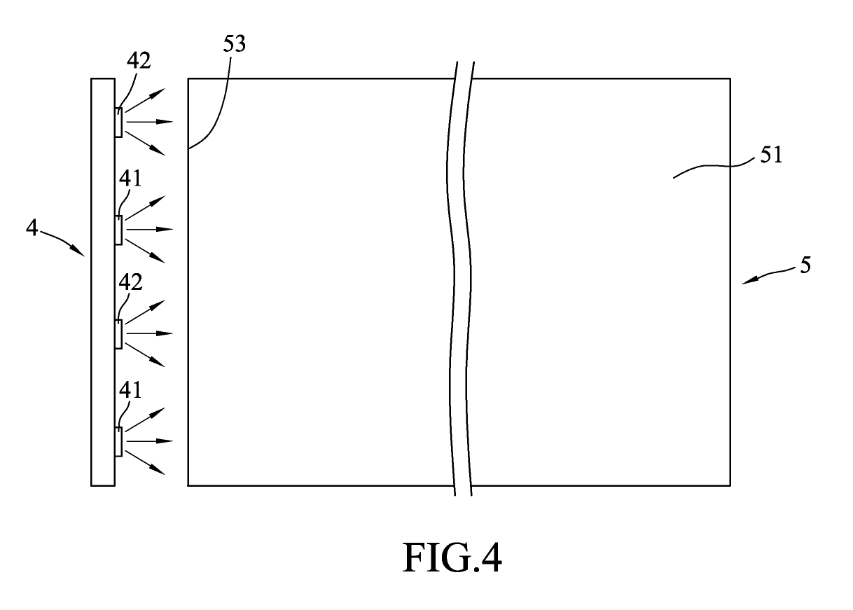

It is worth mentioning that the designs of the first and second embodiments are known as the direct-lit design, where the first light-emitting elements 41 and the second light-emitting elements 42 face the incident surface 12 of the first substrate 1. Referring to FIGS. 3 and 4, a third embodiment of the quantum structure light-emitting module according to the present disclosure has a structure modified from that of the first embodiment. The third embodiment is an edge-lit design, and further includes a light guide plate 5 that is disposed at a side of the incident surface 12 of the first substrate 1. The light guide plate 5 has a light exiting light guide surface 51 facing the incident surface 12 of the first substrate 1, a reflection light guide surface 52 opposite to the light exiting light guide surface 51, and an incident light guide surface 53 interconnecting the light exiting light guide surface 51 and the reflection light guide surface 52. The reflection light guide surface 52 may be formed with a dot array structure, and is capable of reflecting lights. In this embodiment, the first light-emitting elements 41 and the second light-emitting elements 42 are alternatingly arranged along a long side of the incident light guide surface 53 of the light guide plate 5 (see FIG. 4), and face the incident light guide surface 53. The blue light emitted by each of the first light-emitting elements 41 and the red light emitted by each of the second light-emitting elements 42 pass through the incident light guide surface 53 of the light guide plate 5, are directed toward the light exiting light guide surface 51 by the reflection light guide surface 52, and then exit the light exiting light guide surface 51 toward the incident surface 12 of the first substrate 1 of the quantum structure thin film 10.

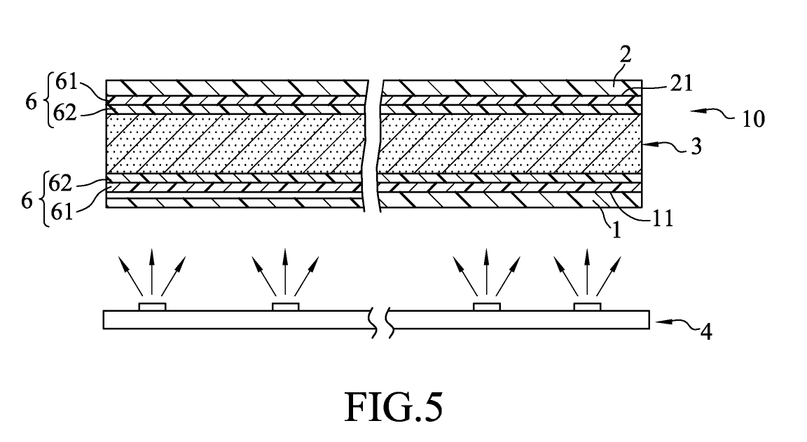

Referring to FIG. 5, a fourth embodiment of the quantum structure light-emitting module according to the present disclosure has a structure modified from that of the first embodiment. In the fourth embodiment, the quantum structure thin film 10 further includes two water resistance units 6 that are respectively disposed between the first substrate 1 and the excitation layer 3 and between the second substrate 2 and the excitation layer 3. Each of the water resistance units 6 includes a water resistance layer 61 and a combination layer 62.

The water resistance layers 61 of the water resistance units 6 are respectively formed on the first surface 11 of the first substrate 1 and the second surface 21 of the second substrate 2. The water resistance layer 61 of each of the water resistance units 6 is made of an organic material and an inorganic material, and is moisture impermeable. The organic material may be hexamethyldisiloxane. The inorganic material may be one of metal nitride, metal oxide and metal nitrogen oxide. The water resistance layer 61 of each of the water resistance units 6 has a thickness ranging from 5 nm to 200 nm, and can prevent the moisture from penetrating through the first substrate 1 and the second substrate 2 and affecting the excitation layer 3.

The combination layer 62 of each of the water resistance units 6 is disposed between the water resistance layer 61 of the resistance unit 6 and the excitation layer 3, and is made of an organic material. In certain embodiment, the combination layer 62 of each of the water resistance units 6 is made of methyl methacrylate, epoxy methacrylate, epoxy acrylates, bisphenol A ethoxylate dimethacrylate, hexanediol diacrylate, bisphenol A epoxy acrylate, and combinations thereof. The combination layers 62 of the water resistance units 6 function to increase adhesive between the water resistance layers 61 of the water resistance units 6 and the excitation layer 3, and also may prevent moisture from penetrating through the first substrate 1 and the second substrate 2. The combination layer 62 of each of the water resistance units 6 has a thickness of around 1 μm.

The combination layers 62 of the water resistance units 6 are formed by coating and thermal curing. The water resistance layers 61 of the water resistance units 6 are formed by sputtering technique. It is worth mentioning that the bonding formed between the organic and inorganic materials during sputtering may ensure the water resistance layers 61 to be less likely to crack, thereby providing superior water-resistant property.

Moisture may adversely affect the service life of the quantum structure light-emitting module. After long-term exposure to moisture, the efficiency of the excitation layer 3 may be decreased due to cracking. The water resistance layers 61 and the combination layers 62 of the water resistance units 6 not only attach well to the excitation layer 3, but provide water-resistant property to the excitation layer 3. In addition, the overall thickness of the water resistance units 6 are controlled so as not to add too much volume to the quantum structure light-emitting module.

It should be noted that, based on practical requirements, one of the water resistance units 6 may be omitted. The water resistance units 6 may also be adapted to the second embodiment, where the water resistance units 6 are respectively disposed between the first microstructures 13 and the excitation layer 3, and between the second microstructures 23 and the excitation layer 3.

To sum up, the quantum structure light-emitting module of this disclosure utilizes the blue light emitted by the first light-emitting elements 41 to excite the quantum structures 31 to emit the green light. The blue light and the green light are mixed with the red light emitted by the second light-emitting elements 42 to generate the white light. A conventional light-emitting module generates red light by using blur light excitation. The quantum structure light-emitting module of this disclosure has a stronger red light intensity, thereby allowing the display device including the quantum structure light-emitting module to have superior color gamut, color saturation and intensity of the white light. When the second light-emitting elements 42 include K₂SiF₆:Mn⁴⁺ phosphor, the color gamut and the color saturation of the display device are further improved.

In the description above, for the purposes of explanation, numerous specific details have been set forth in order to provide a thorough understanding of the exemplary embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A quantum structure light-emitting module comprising:
a quantum structure thin film including
a first substrate that has a first surface and an incident surface opposite to said first surface,
a second substrate that is spaced apart from said first substrate, and that has a second surface facing said first surface of said first substrate and a light exiting surface opposite to said second surface, and
an excitation layer that is disposed between said first surface of said first substrate and said second surface of said second substrate, and that includes a plurality of quantum structures, said quantum structures being one of quantum dots and quantum rods, and being made of one of cesium lead halide and organic ammonium lead halide; and
a light-emitting unit that is spaced apart from said quantum structure thin film, and that includes a first light-emitting element emitting a blue light and a second light-emitting element emitting a red light,
wherein the blue light emitted by said first light-emitting element and the red light emitted by said second light-emitting element pass through said first substrate and enter said excitation layer, the blue light excites said quantum structures to emit a green light, and the red light, the blue light and the green light are mixed and exit said light exiting surface of said second substrate.

2. The quantum structure light-emitting module as claimed in claim 1, wherein the cesium lead halide is CsPbBr₃, and the organic ammonium lead halide is CH₃NH₃PbBr₃.

3. The quantum structure light-emitting module as claimed in claim 1, wherein said second light-emitting element is a red light emitting diode including potassium fluorosilicate phosphor.

4. The quantum structure light-emitting module as claimed in claim 3, wherein said quantum structures are quantum dots each having a dimension ranging from 9 nm to 13 nm.

5. The quantum structure light-emitting module as claimed in claim 4, wherein the green light emitted by said quantum structures has a dominant wavelength ranging from 520 nm to 540 nm.

6. The quantum structure light-emitting module as claimed in claim 1, wherein said first substrate further has a plurality of first microstructures formed on said incident surface.

7. The quantum structure light-emitting module as claimed in claim 6, wherein said second substrate further has a plurality of second microstructures formed on said light exiting surface.

8. The quantum structure light-emitting module as claimed in claim 1, wherein said first light-emitting element and said second light-emitting element face said incident surface of said first substrate.

9. The quantum structure light-emitting module as claimed in claim 1, further comprising a light guide plate that is disposed at a side of said incident surface of said first substrate, said light guide plate has a light exiting light guide surface facing said incident surface of said first substrate, a reflection light guide surface opposite to said light exiting light guide surface, and an incident light guide surface interconnecting said light exiting light guide surface and said reflection light guide surface, said first light-emitting element and said second light-emitting element facing said incident light guide surface.

10. The quantum structure light-emitting module as claimed in claim 1, wherein said quantum structure thin film further includes at least one water resistance unit that is disposed between one of said first substrate and said excitation layer, and said second substrate and said excitation layer, said water resistance unit including a water resistance layer that is made of an organic material and an inorganic material and that is moisture impermeable.

11. The quantum structure light-emitting module as claimed in claim 10, wherein said organic material of said water resistance layer is hexamethyldisiloxane, said inorganic material of said water resistance layer being one of metal nitride, metal oxide and metal nitrogen oxide.

12. The quantum structure light-emitting module as claimed in claim 10, wherein said water resistance layer has a thickness ranging from 5 nm to 200 nm.

13. The quantum structure light-emitting module as claimed in claim 10, wherein said water resistance unit further includes a combination layer that is disposed between said water resistance layer and said excitation layer and that is made of an organic material.

14. The quantum structure light-emitting module as claimed in claim 13, wherein said combination layer is made of methyl methacrylate, epoxy methacrylate, epoxy acrylates, bisphenol A ethoxylate dimethacrylate, hexanediol diacrylate, bisphenol A epoxy acrylate, and combinations thereof.

15. The quantum structure light-emitting module as claimed in claim 1, wherein said quantum structure thin film further includes two water resistance units that are respectively disposed between said first substrate and said excitation layer and between said second substrate and said excitation layer, each of said water resistance units including a water resistance layer that is made of an organic material and an inorganic material and that is moisture impermeable.

16. The quantum structure light-emitting module as claimed in claim 15, wherein said organic material of said water resistance layer of each of said water resistance units is hexamethyldisiloxane, said inorganic material of said water resistance layer of each of said water resistance units being one of metal nitride, metal oxide and metal nitrogen oxide.

17. The quantum structure light-emitting module as claimed in claim 15, wherein said water resistance layer of each of said water resistance units has a thickness ranging from 5 nm to 200 nm.

18. The quantum structure light-emitting module as claimed in claim 15, wherein each of said water resistance units further includes a combination layer that is disposed between said water resistance layer of said water resistance unit and said excitation layer and that is made of an organic material.

19. The quantum structure light-emitting module as claimed in claim 18, wherein said combination layer of each of said water resistance units is made of methyl methacrylate, epoxy methacrylate, epoxy acrylates, bisphenol A ethoxylate dimethacrylate, hexanediol diacrylate, bisphenol A epoxy acrylate, and combinations thereof.
